(19) United States
(12) Patent Application Publication
(10) Pub. No.: US 2008/0220575 A1
(43) Pub. Date: Sep. 11, 2008

(54) METHOD OF FABRICATING DYNAMIC RANDOM ACCESS MEMORY

(75) Inventor: Yi-Nan Su, Taoyuan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: UNITED MICROELECTRONICS CORP., Hsinchu (TW)

(21) Appl. No.: 12/126,942

(22) Filed: May 26, 2008

Related U.S. Application Data
(62) Division of application No. 11/306,815, filed on Jan. 12, 2006.

(51) Int. Cl. H01L 27/108

(52) U.S. Cl. 438/243; 257/E27.092

(57) ABSTRACT

A method of fabricating a dynamic random access memory is provided. A trench capacitor is formed in a substrate and an isolation structure is formed on the trench capacitor. A gate structure and a passing gate structure are formed on the substrate. The gate structure is on one side of the passing gate structure. A source region and a drain region are formed in the substrate on both sides of the gate structure. A dielectric layer is formed on the substrate. A contact is formed in the dielectric layer and the isolation structure, at the other side of the passing gate structure, and is coupled to the trench capacitor. Since the contact is formed at the other side of the passing gate structure, the contact would not coupled to the source and drain regions when misalignment occurs.

### CROSS-REFERENCE TO RELATED APPLICATION

This application is a divisional of an application Ser. No. 11/306,815, filed on Jan. 12, 2006, now pending. The entirety of each of the above-mentioned patent applications is hereby incorporated by reference herein and made a part of this specification.

### BACKGROUND OF THE INVENTION

1. Field of Invention

The present invention relates to a structure and a fabrication method of a semiconductor device. More particularly, the present invention relates to a structure and a fabrication method of a dynamic random access memory (DRAM).

2. Description of Related Art

The DRAM is using a capacitor to store information. Data content of each memory cell is read by judging the charges stored in the capacitor. The size for the present memory cell is rather small. In order to increase the capacitance of the capacitor and reduce the possibility in error reading on data, and further reduce the refreshing frequency for increasing the operation efficiency, the usual way is increasing the surface area of lower electrode of the capacitor. By increasing the surface area of the capacitor, it can thus provide the sufficient storage capacitance. In order to satisfy the need in surface area of the capacitor and the integration of memory cells, the trench capacitor has been the popular option.

FIG. 1A is a top view, schematically illustrating the DRAM using a conventional trench capacitor. FIG. 1B is a cross-sectional view along the line I-I′ in FIG. 1A. In FIG. 1A and FIG. 1B, the DRAM includes a substrate 100, a transistor 102, a passing gate structure 104, an isolation structure 106, a trench capacitor 108, an inter-layer dielectric layer 110, and a contact 112. The contact 112 is coupled to the trench capacitor 108.

However, when the contact window is under the photolithography process, due to rather small process, the misalignment easily occurs, causing the contact 112 to be electrically connected with the source region and drain region 114 of the transistor 102 at the circle 103. As a result, the memory cell gets failure and the production yield of the memory is affected.

### SUMMARY OF THE INVENTION

With an objective, the invention provides a method for fabricating DRAM with improvement of production yield about the contact alignment.

With another objective, the invention provides a method for fabricating DRAM, capable of increasing the yield of the memory device.

The invention provides a DRAM, includes a substrate, a trench capacitor, a passing gate structure, a transistor, and a contact. The substrate has a trench. The trench capacitor is disposed in the trench. The passing gate structure is disposed on the trench capacitor. The transistor is disposed on the substrate at one side of the passing gate structure. The contact is disposed on the substrate at the other side of the passing gate structure, and the contact is coupled to the trench capacitor.

In an embodiment, the foregoing trench capacitor includes a lower electrode, a capacitance dielectric layer, and an upper electrode. The lower electrode is disposed on the periphery of the trench in the substrate. The upper electrode fills the trench. The capacitance dielectric layer is disposed between the upper electrode and the lower electrode. A material for the capacitance dielectric material includes, for example, silicon oxide/ silicon nitride/ silicon oxide (ONO).

In an embodiment, the foregoing DRAM further includes an isolation structure, disposed between the passing gate structure and the trench capacitor.

The invention provides another DRAM, includes a substrate, a first transistor, a second transistor, a first trench capacitor, a second trench capacitor, a first passing gate structure, a second passing gate structure, a transistor, and a contact. The substrate has a device isolation structure. The first transistor is disposed on the substrate at one side of the device isolation structure. The second transistor is disposed on the substrate at the other side of the device isolation structure. The first trench capacitor is disposed between the first transistor and the device isolation structure. The second trench capacitor is disposed between the second transistor and the device isolation structure. The first passing gate structure is disposed on the first trench capacitor. The second passing gate structure is disposed on the second trench capacitor. The contact is disposed between the first passing gate structure and the second passing gate structure, and is coupled to the first trench capacitor and the second trench capacitor.

In an embodiment, the foregoing first trench capacitor includes a first lower electrode, a first capacitance dielectric layer, and a first upper electrode. The first lower electrode is disposed in the substrate at the periphery of the upper electrode. The first capacitance dielectric layer is disposed between the first upper electrode and the first lower electrode. A material of the first capacitance dielectric layer includes silicon oxide/ silicon nitride/ silicon oxide (ONO).

In an embodiment, the foregoing second trench capacitor includes a second lower electrode, a second capacitance dielectric layer, and a second upper electrode. The second lower electrode is disposed in the substrate at the periphery of the upper electrode. The second capacitance dielectric layer is disposed between the second upper electrode and the second lower electrode. A material of the second capacitance dielectric layer includes silicon oxide/ silicon nitride/ silicon oxide (ONO).

In an embodiment, the foregoing DRAM further includes a first isolation structure, disposed between the first passing gate structure and the first trench capacitor. In addition, the foregoing DRAM further includes a second isolation structure, disposed between the second passing gate structure and the second trench capacitor.

The invention further provides a method for fabricating a DRAM, including providing a substrate, and forming a trench capacitor in the substrate. Then, an isolation structure is formed on the trench capacitor. A gate structure and a passing gate structure are formed on the substrate. The passing gate structure is on the isolation structure, and the gate structure is at one side of the passing gate structure. Then, a source/drain region is formed in the substrate at each side of the gate structure. The gate structure with the source/drain region forms a transistor. A dielectric layer covers over the substrate. Then, a contact is formed in the dielectric layer and the isolation structure, at another side of the passing gate structure. Also and, the contact is coupled to the trench capacitor.

In an embodiment, the method for forming the trench capacitor includes forming a trench in the substrate, and the substrate at the periphery of the trench serves as the lower electrode. Then, a conformal dielectric layer is formed over the substrate. This dielectric layer serves as a capacitance dielectric layer. After then, a conductive layer is formed over the substrate. This conductive layer fully fills the trench. A portion of the conductive layer and the dielectric layer other than the trench is removed, so that the upper electrode is formed. In addition, a material for the capacitance dielectric layer includes, for example, silicon oxide/ silicon nitride/ silicon oxide (ONO).

The invention further provides a method for fabricating a DRAM, including providing a substrate and forming a device isolation structure in the substrate. Then, a first trench capacitor and a second trench capacitor are formed in the substrate at both sides of the device isolation structure. A first isolation structure and a second isolation structure are respectively formed on the first trench capacitor and the second trench capacitor. A first gate structure and a second gate structure are formed on the substrate. A first passing gate structure and a second passing gate structure are respectively formed on the first isolation structure and the second isolation structure. The first passing gate structure and the second passing gate structure are located between the first gate structure and the second gate structure. Several source/drain regions are formed in the substrate at sides of the first gate structure and the second gate structure. A dielectric layer is formed to cover over the substrate. A contact is formed in the dielectric layer between the first passing gate structure and the second passing gate structure, the first isolation structure, and the second isolation structure. The contact is coupled to the first trench capacitor and the second trench capacitor.

In an embodiment, the method for forming the first trench capacitor and second trench capacitor includes forming a first trench and a second trench in the substrate. The substrate at the periphery of the first trench and the second trench serves as a first lower electrode and a second electrode. Then, a conformal dielectric layer and a conductive layer are sequentially formed over the substrate. The dielectric layer serves as a capacitance dielectric layer and the conductive layer fills the first trench and the second trench. After removing a portion of the dielectric layer and the conductive layer other than the first trench and the second trench, a first upper electrode and a second upper electrode are respectively formed in the first trench and the second trench. A material for the first capacitance dielectric layer and the second capacitance dielectric layer includes, for example, silicon oxide/ silicon nitride/ silicon oxide (ONO).

In the invention, since the transistor is formed at one side of the passing gate structure and the contact is formed at the other side of the passing gate structure and coupling to the trench capacitor, the process window for the contact is therefore not limited by the source region and drain region. In addition, since the process for forming the trench capacitor is after the formation of the device isolation structure, the process window for the contact is not limited by the device isolation structure. In summary, the present invention can significantly improve the process window of contact, and further improve yield and reliability of the memory device.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view, schematically illustrating the DRAM using a conventional trench capacitor.

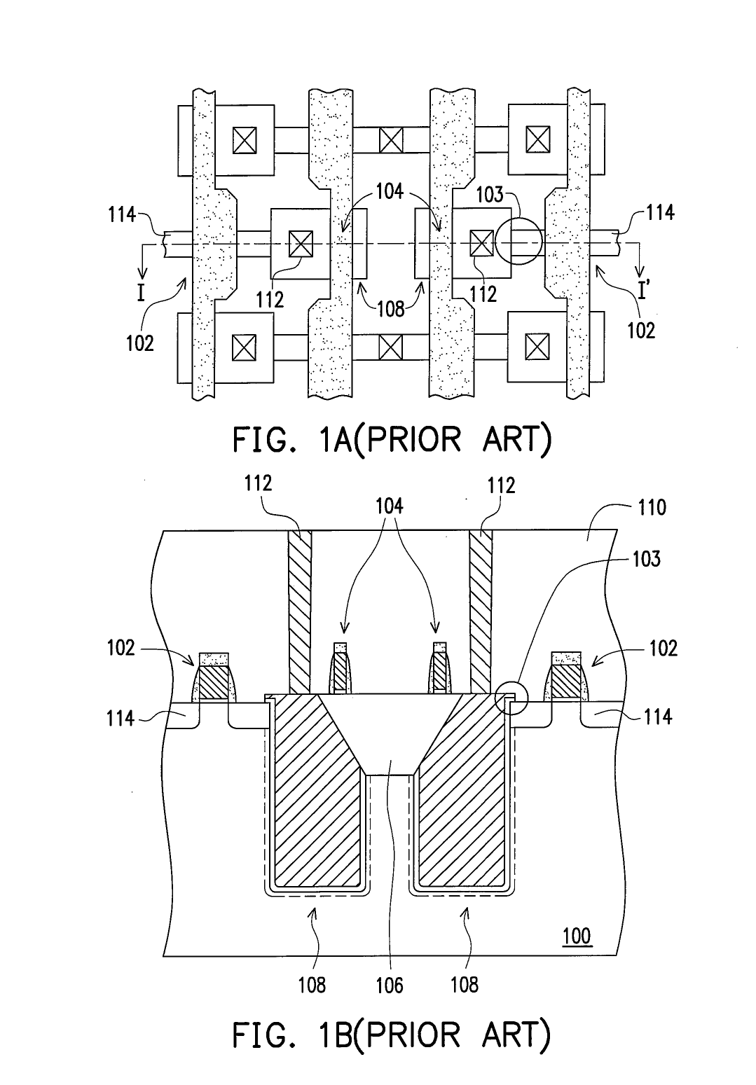

FIG. 1B is a cross-sectional view along the line I-I′ in FIG. 1A.

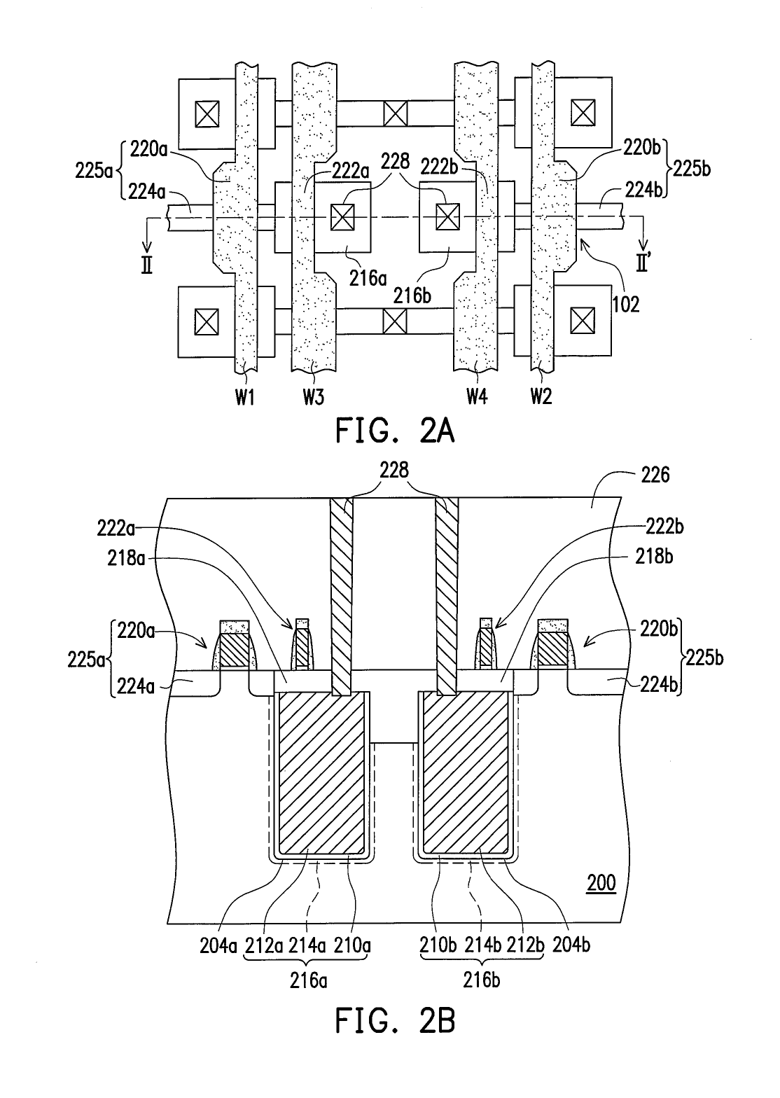

FIG. 2A a top view, schematically illustrating a DRAM, according to an embodiment of the invention.

FIG. 2B is a cross-sectional view along the line II-II′ in FIG. 2A.

FIG. 3A is a top view, schematically illustrating a DRAM, according to another embodiment of the invention.

FIG. 3B is a cross-sectional view along the line III-III′ in FIG. 3A.

FIGS. 4A-4F are cross-sectional views, schematically illustrating the fabrication processes to form a DRAM, according to an embodiment of the invention.

FIG. 4G is a cross-sectional view, schematically illustrating the fabrication processes to form a DRAM, according to another embodiment of the invention.

### DESCRIPTION OF THE PREFERRED EMBODIMENTS

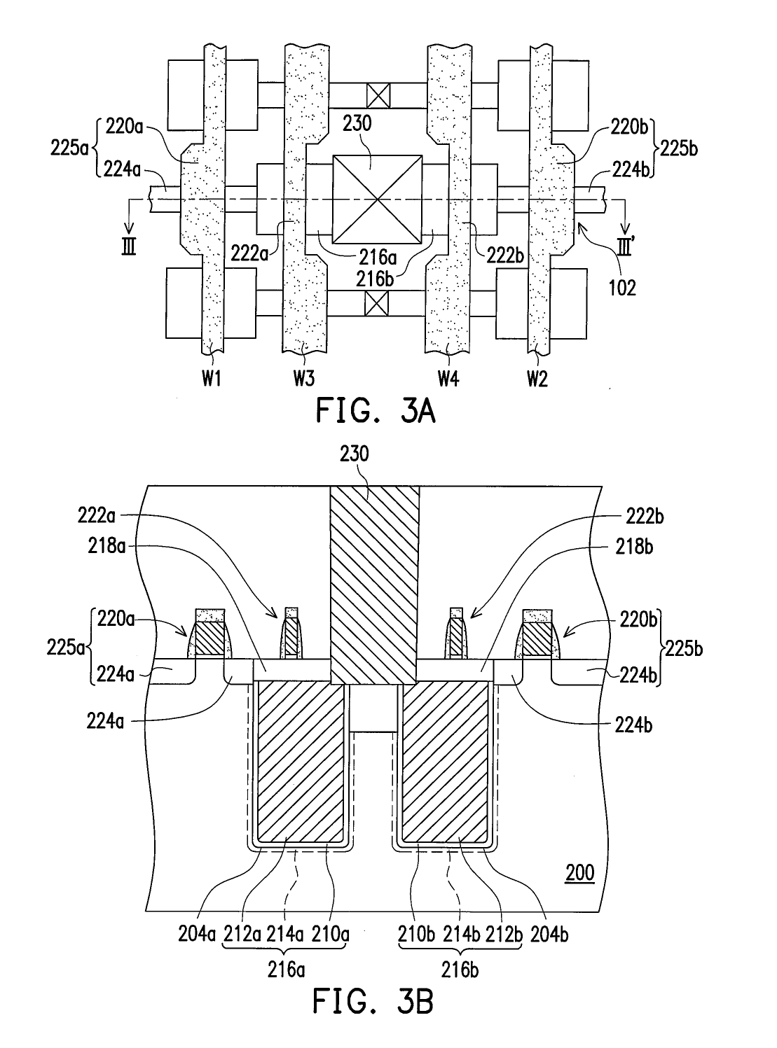

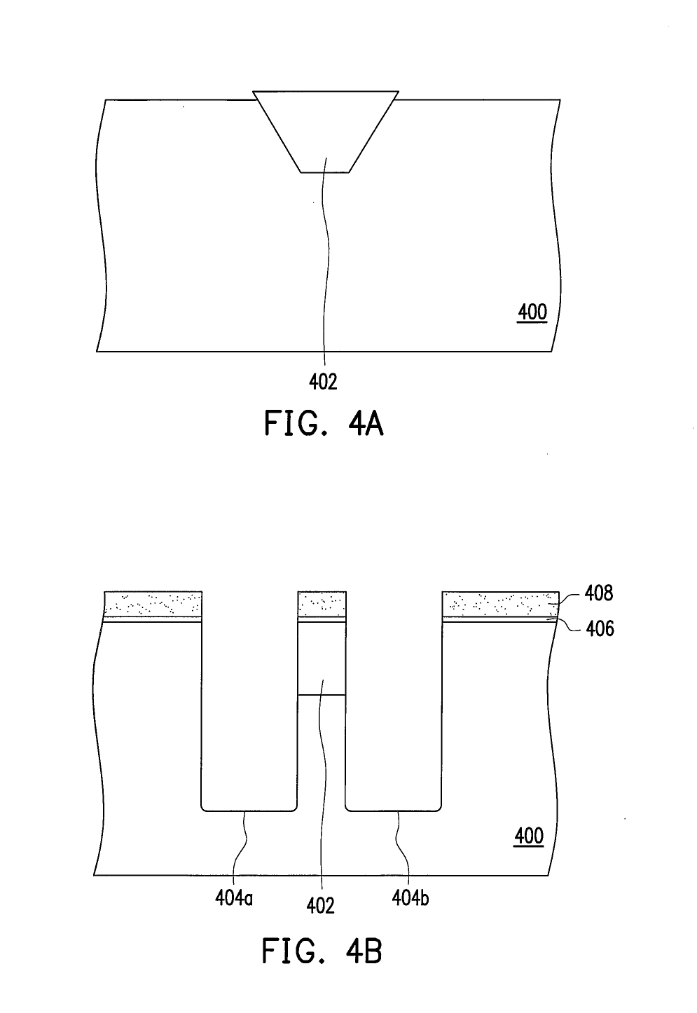

FIG. 2A a top view, schematically illustrating a DRAM, according to an embodiment of the invention. FIG. 2B is a cross-sectional view along the line II-II′ in FIG. 2A. In FIG. 2A and FIG. 2B, only a portion of the memory cell array in a DRAM is shown, however, the invention is not only limited to this portion. The arrangement between each of the device structures can be the repeat of structure in FIG. 2 at the directions of up-to-down or left-to-right.

In FIG. 2A and FIG. 2B, the DRAM of the invention is formed from a substrate 200, a device isolation structure 202, a trench capacitor 216a, a trench capacitor 216b, a first isolation structure 218a, a second isolation structure 216b, a passing gate structure 222a, a passing gate structure 222b, a transistor 225a, a transistor 225b, and a contact 228. The substrate is, for example, a silicon substrate, having trenches 204a and 204b.

In addition, the transistor 225a is disposed on the substrate 200 at one side of the device isolation structure 202. The transistor 225b is disposed on the substrate 200 at the other side of the device isolation structure 202. The transistor 225a includes a gate structure 220a and a source/drain region 224a. The transistor 225b includes a gate structure 220b and a source/drain region 224b. The gate structure 220a in the array of memory cells can be a part of the word line (W1), and the gate structure 220b in the array of memory cells can be a part of the word line (W2).

In addition, the trench 204a is located between the transistor 225a and the device isolation structure 202, and the trench 204b is located between the transistor 225b and the device isolation structure 202. The trench capacitor 216a is disposed in the trench 204a. The trench capacitor 216a includes the capacitance dielectric layer 210a and upper electrode 212a. The capacitance dielectric layer 210a is disposed on the surface of the trench 204a. A material for the capacitance dielectric layer 210a includes, for example, silicon oxide/silicon nitride/silicon oxide (ONO). The upper electrode 212a is disposed on the capacitance dielectric layer 210a and fills the trench 204a. A material for the upper electrode 212a includes, for example, doped polysilicon. In addition, the substrate 200 at the periphery of the upper electrode 212a can be, for example, serving as a lower electrode 214a. The trench capacitor 216b is disposed in the trench 204b. The trench capacitor 216b includes the capacitance dielectric layer 210b and upper electrode 212b. The capacitance dielectric layer 210b is disposed on the surface of the trench 204b. A material for the capacitance dielectric layer 210b includes, for example, ONO. The upper electrode 212b is disposed on the capacitance dielectric layer 210b and fills the trench 204b. A material for the upper electrode 212b includes, for example, doped polysilicon. In addition, the substrate 200 at the periphery of the upper electrode 212b can be, for example, serving as a lower electrode 214b.

Further, the first isolation structure 218a is disposed between the passing gate structure 222a and the trench capacitor 216a, and the second isolation structure 218b is disposed between the passing gate structure 222b and the trench capacitor 216b. A material for the first isolation structure 218a and the second isolation structure 218b is, for example, silicon oxide.

On the other hand, the passing gate structure 222a is disposed on the trench capacitor 216a. The passing gate structure 222a is disposed on the trench capacitor 216b. The passing gate structure 222a in the array of memory cells can be a part of the word line (W3), and the passing gate structure 222b in the array of memory cells can be a part of the word line (W4).

In addition, an inter-layer dielectric layer 226 is disposed over the substrate 200. A material for the inter-layer dielectric layer 226 is, for example, silicon oxide. The contact 228 is formed in the first isolation structure 218a and the second isolation structure 218b between the passing gate structure 222a and the passing gate structure 222b, and in the inter-layer dielectric layer 226 the contact 228 is coupled to the trench capacitor 216a and the trench capacitor 216b. A material for the contact 228 includes, for example, tungsten.

Another embodiment of DRAM, similar to the previous DRAM, in the invention is described as follows.

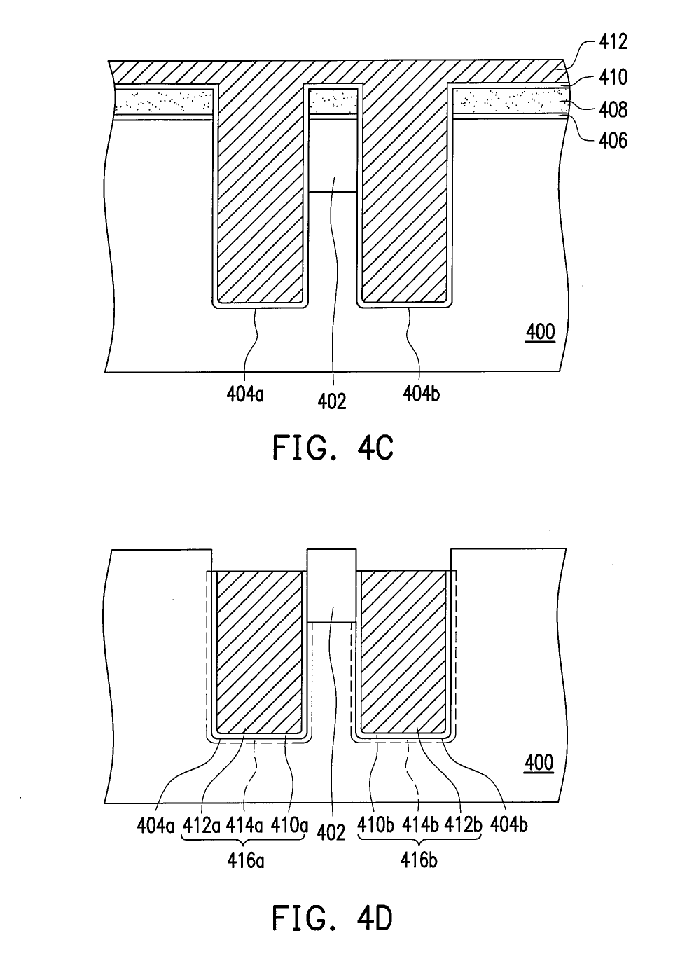

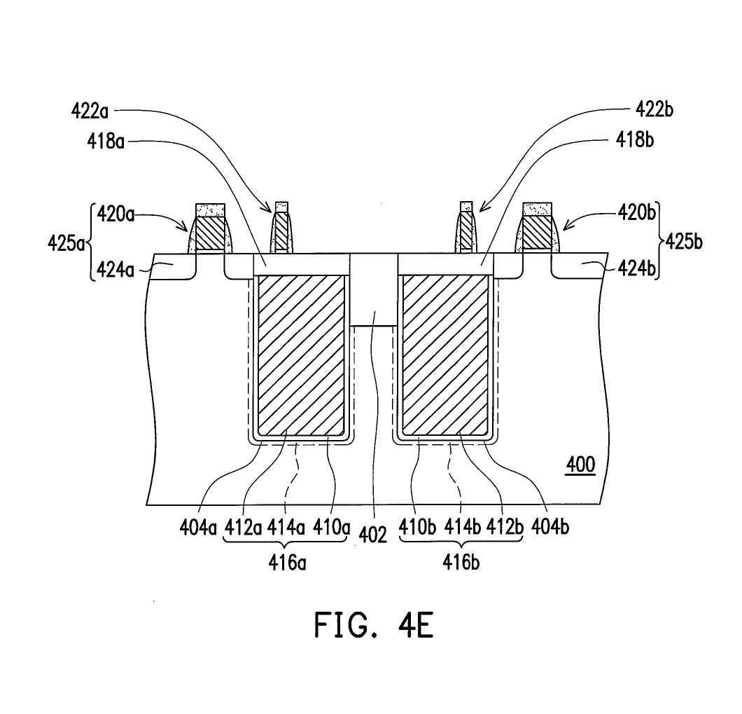

FIG. 3A is a top view, schematically illustrating a DRAM, according to another embodiment of the invention. FIG. 3B is a cross-sectional view along the line III-III′ in FIG. 3A. In FIG. 3A and FIG. 3B, only a portion of the memory cell array in a DRAM is shown, however, the invention is not only limited to this portion. The arrangement between each of the device structures can be the repeat of structure in FIG. 2 at the directions of up-to-down or left-to-right.

In FIG. 3A and FIG. 3B, the devices similar to those in FIG. 2 and FIG. 2B are indicated with the same numerals, and the descriptions are omitted. Here, the differences are described. Since the upper electrodes 212a, 212bunder operation of the memory have the same voltage level, a single contact 230 can be used in the DRAM of FIG. 3A and FIG. 3B, to replace the contacts 228. The contact 230 is disposed between the passing gate structure 222a and the passing gate structure 222b, and is coupled to trench capacitors 216a and 216b. A material for the contact 230 is, for example, tungsten.

Since the transistor is disposed at one side of the passing gate structure and the contact is disposed at another side of the passing gate structure, it allows a larger tolerance for fabrication error, so as to prevent the contact from coupling to the source/drain region. Therefore, the DRAM of the invention has higher yield and reliability.

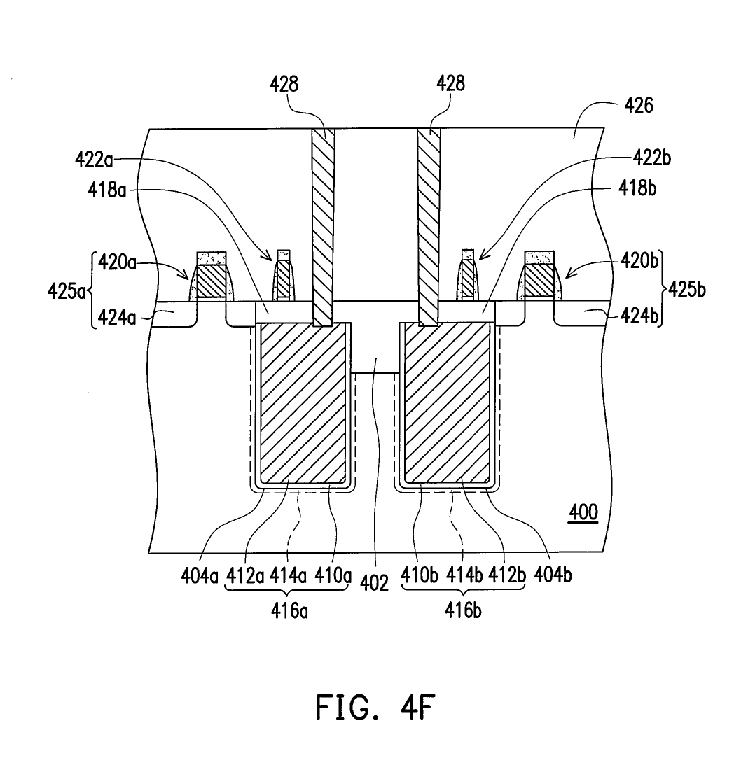

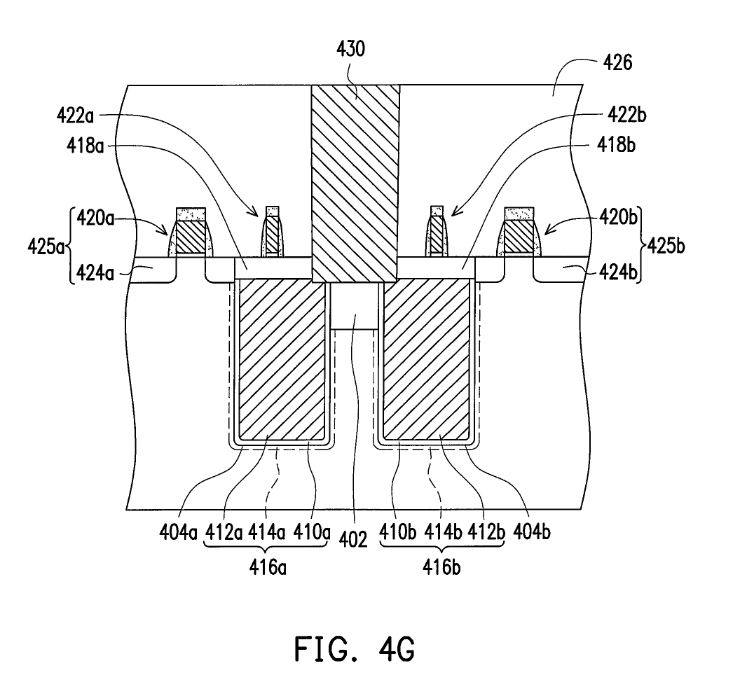

FIGS. 4A-4F are cross-sectional views, schematically illustrating the fabrication processes to form a DRAM, according to an embodiment of the invention.

In FIG. 4A, a substrate 400, such as a silicon substrate, is provided. The substrate 400 has been formed with a device isolation structure 402. The device isolation structure 402 is, for example, a shallow trench isolation structure and the material is, for example, silicon nitride.

Then, in FIG. 4B, the trenches 404a and 404b are formed in the substrate 400 at both side of the device isolation structure 402. A portion of the device isolation structure 402 is removed during forming the trench 404a and the trench 404b. The method for forming the trench 404a and the trench 404b includes, for example, sequentially forming a first dielectric layer (not shown) and a second dielectric layer (not shown) over the substrate 400. The first dielectric layer is, for example, silicon oxide, and the second dielectric layer is, for example, silicon nitride. Then, the first dielectric layer and the second dielectric layer are patterned, so as to form a pad oxide layer 406a and a mask layer 408. Then, it is the formed by performing an etching process by using the mask layer 408 as a mask.

In FIG. 4C, a conformal dielectric layer 410 is formed over the substrate 400. A material layer for the dielectric layer 410 is, for example, ONO. The method for forming the dielectric layer 410 is, for example, chemical vapor deposition. Then, a conductive layer 412 is formed over the substrate 400. The conductive layer 412 fills the trench 404a and the trench 404b. A material for the conductive layer 412 is, for example, doped polysilicon. The method for forming the conductive layer 412 is, for example, chemical vapor deposition.

In FIG. 4D, a portion of the conductive layer 412 and the dielectric layer 410 other than the trench 404a and the trench 404b is removed. As a result, a capacitance dielectric layer 410a is formed on the surface of the trench 404a, and an upper electrode 412a is formed in the trench 404a. A capacitance dielectric layer 410b is formed on the surface of the trench 404b, and an upper electrode 412b is formed in the trench 404b. The method for removing the portion of the conductive layer 412 and the dielectric layer 410 other than the trench 404a and the trench 404b is, for example, performing a chemical mechanical polishing process by using the mask layer 408 as the polishing stop. The substrate 400 at the periphery of the trench 404a and 404b are respectively serving as a lower electrode 414a and a lower electrode 414b. The capacitance dielectric layer 410a, the upper electrode 412a, and the lower electrode 414a form a trench capacitor 416a; the capacitance dielectric layer 410b, the upper electrode 412b, and the lower electrode 414b form a trench capacitor 416b. An etching back process is performed on the upper electrode 412a and the upper electrode 412b. The mask layer 408 and the pad oxide layer 406 are removed while a portion of the capacitance dielectric layers 410a and 410b is removed, too.

In FIG. 4E, an insulation layer (not shown) is formed over the substrate 400. The insulation layer fully fills the trenches 404a and 404b. A material for the insulation material is, for example, silicon oxide. After then, a portion of the insulation layer other than the trenches 404a and 404b is removed, so as to respectively form a first isolation structure 418a and a second isolation structure 418b on the trench capacitors 416a and 416b. The method for removing the portion of the insulation layer other than the trenches 404a and 404b is, for example, chemical mechanical polishing process. The first isolation structure 418a and the second isolation structure 418b are serving as the passing gate isolation (PGI) structure. A gate structure 420a and a gate structure 420b are formed on the substrate 400. A passing gate structure 422a and a passing gate structure 422b are also respectively formed on the first isolation structure 418a and the second isolation structure 418b. The passing gate structure 422a and the passing gate structure 422b are located between the gate structure 420a and the gate structure 420b. The source/drain regions 424a are formed in the substrate 400 at both sides of the gate structure 420a, so as to form the transistor 425a; the source/drain regions 424b are formed in the substrate 400 at both sides of the gate structure 420b, so as to form the transistor 425b. The source/drain region 424a at one side of the gate structure 420a is coupled to trench capacitor 416a, and the source/drain region 424b at one side of the gate structure 420b is coupled to trench capacitor 416b.

In FIG. 4F, an inter-layer dielectric layer 426 is formed over the substrate 400 to cover the substrate 400, the gate structure 420a, the gate structure 420b, the passing gate structure 422a, the passing gate structure 422b, the device isolation structure 402, the first isolation structure 418a, and the second isolation structure 418b. A contact 428 is formed in the inter-layer dielectric layer 426 between the passing gate structure 422a and the passing gate structure 422b, the first isolation structure 418a, and the second isolation structure 418b. The contact 228 is coupled to the upper electrodes 412a and 412b. Remarkably, even under the situation of poor alignment, the contact 428 is still not contacting with the source/drain regions 424a and 424b.

FIG. 4G is a cross-sectional view, schematically illustrating the fabrication processes to form a DRAM, according to another embodiment of the invention. Since the processes before forming the contact for the DRAM in FIG. 4G are the same as the processes for the DRAM in FIG. 4F, the processes before forming the contact are not re-described.

In FIG. 4G, another contact 430 is formed over the substrate 400, to replace the contact 428 in FIG. 4F. The contact 430 is coupled to the trench capacitors 416a and 416b. Even under the situation of poor alignment, the contact 430 is still not contacting with the source/drain regions 424a and 424b.

In summary, the DRAM of the invention at least has the advantages as follows.

1. The transistor of the present invention is formed at one side of the passing gate structure, the contact is formed at another side of the passing gate structure with connecting to the trench capacitor. As a result, the process window is determined by the passing gate structure but not limited by the source/drain region. Thus, the present invention prevents the conventional issues about process window of contact, which is limited by both the passing gate structure and the source/drain region. In addition, since the contact of the adjacent two trench capacitors is incorporated in the same fabrication region, and there no other structure between the two contacts, the process window is significantly improved, and the yield of the memory device is improved.

2. Since the process for forming the trench capacitor is performed after the device isolation structure having been formed, the conventional issues are significantly solved. As a result, the process window of the contact is not limited to the device isolation structure, and can be significantly improved.

3. Since the invention changes the position of the contact, it can prevent the metal silicide at the interface of contact and the trench capacitor from extending to the source/drain region due to poor control of the fabrication process.

4. Since the invention does not need the photolithography process to form the isolation structure above the trench capacitor, the fabrication process can be simplified.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A method for fabricating a dynamic random access memory (DRAM), comprising:
providing a substrate;
forming a trench capacitor in the substrate;
forming an isolation structure over the trench capacitor;
forming a gate structure and a passing gate structure, wherein the passing gate structure is located over the isolation structure, and the gate structure is located at first side of the passing gate structure;
forming a source/drain region in the substrate at each side of the gate structure, wherein the gate structure and the source/drain region form a transistor;
forming a dielectric layer, covering over the substrate; and
forming a contact in the dielectric layer at a second side of the passing gate structure and the isolation structure, and the contact coupled to trench capacitor.

2. The method of claim 1, wherein a process to form trench capacitor comprises:
forming a trench in the substrate, a periphery of the trench of the substrate serving as a lower electrode;
forming a conformal dielectric layer over the substrate, the dielectric layer serving as a capacitance dielectric layer;
forming a conductive layer over the substrate, the substrate filling the trench; and
removing a portion of the conductive layer and the dielectric layer other than the trench, so as to form an upper electrode in the trench.

3. The method for claim 2, a material for forming the capacitance dielectric layer comprises silicon oxide/silicon nitride/silicon oxide (ONO).

4. A method for fabricating a dynamic random access memory (DRAM), comprising:
providing a substrate;
forming a device isolation structure in the substrate;
forming a first trench capacitor and a second trench capacitor in the substrate at both sides of the device isolation structure;
forming a first isolation structure and a second isolation structure respectively over the first trench capacitor and the second trench capacitor;
forming a first gate structure, a second gate structure, a first passing gate structure, and a second passing gate structure, wherein the first passing gate structure and the second passing gate structure are respectively over the first isolation structure and the second isolation structure, wherein the first passing gate structure and the second passing gate structure are located between the first gate structure and the second gate structure;
forming a plurality of source/drain regions in the substrate at a plurality of sides of the first gate structure and the second gate structure;
forming a dielectric layer, covering over the substrate; and
forming a contact in the dielectric layer between first passing gate structure and the second passing gate structure, and in the first and the second isolation structures, wherein the contact is coupled to the first trench capacitor and the second trench capacitor.

5. The method of claim 4, wherein a process for forming the first trench capacitor and the second trench capacitor comprises:
forming a first trench and a second in the substrate, a periphery of the first trench and the second trench of the substrate serving as a first lower electrode and a second lower electrode;
forming a conformal dielectric layer over the substrate, the dielectric layer serving as a first capacitance dielectric layer and a second capacitance dielectric layer;
forming a conductive layer over the substrate, the conductive layer filling the first trench and the second trench; and
removing a portion of the conductive layer and the dielectric layer other than the first trench and the second trench, so as to respectively form a first upper electrode and a second upper electrode in the first trench and the second trench.

6. The method of claim 5, wherein a material for forming the first capacitance dielectric layer and the second capacitance dielectric layer comprises silicon oxide/silicon nitride/silicon oxide (ONO).
